(19) United States
(12) Patent Application Publication
(10) Pub. No.: US 2025/0185345 A1
(43) Pub. Date: Jun. 5, 2025

(54) OFFSET STAGGERED STACKED FIELD EFFECT TRANSISTOR (SFET) DEVICES

(71) Applicant: International Business Machines Corporation, Armonk, NY (US)

(72) Inventors: Ruilong Xie, Niskayuna, NY (US); Tao Li, Slingerlands, NY (US); Shay Reboh, Guilderland, NY (US); Debarghya Sarkar, Latham, NY (US); Chen Zhang, Santa Clara, CA (US)

(21) Appl. No.: 18/529,255

(22) Filed: Dec. 5, 2023

(51) Int. Cl. H01L 29/66; H01L 21/8238; H01L 27/02; H01L 27/092; H01L 29/06; H01L 29/423; H01L 29/775; H01L 29/786

(52) U.S. Cl. CPC H10D 84/038; H10D 30/014; H10D 30/43; H10D 30/6735; H10D 30/6757; H10D 62/121; H10D 84/0167; H10D 84/017; H10D 84/0172; H10D 84/0186; H10D 84/0188; H10D 84/85; H10D 88/00; H10D 88/01

(57) ABSTRACT

Embodiments are disclosed for a semiconductor structure. The semiconductor structure includes a standard logic cell having a top field effect transistor (FET) and a bottom FET. Further, the top FET includes multiple top channels, Additionally, the top channels are in contact with a first dielectric liner of a first gate cut region. Further, the bottom FET includes multiple bottom channels. Additionally, the bottom channels are in contact with a second dielectric liner of a second gate cut region. Further, the top FET and the bottom FET share a gate. Additionally, the top FET is disposed in an offset position with respect to the bottom FET.

### FIELD OF THE INVENTION

The present invention generally relates to semiconductor structures, and more particularly to offset staggered stacked field effect transistor (SFET) semiconductor devices.

### BACKGROUND

Integrated circuit (IC) chips are formed on semiconductor wafers at increasingly smaller scale. In current technology nodes, such as 7, 10 and 14 nanometer technologies, transistor devices are constructed as three-dimensional (3D) fin FET (FINFET) structures. However, chipmakers face a myriad of challenges at 5 nm, 3 nm and beyond. Currently, traditional chip scaling continues to slow as process complexities and costs escalate at each node.

A potential solution to this chip scaling problem is gate all around technology. One example of a complex gate all around technology is an SFET where nFET and pFET nanowires/nanosheets are vertically stacked on top of each other.

An SFET semiconductor structure includes stacks of devices (e.g., FETs), divided into cells of the individual stacks. Further, the individual devices are wired into computer circuits. However, in an SFET semiconductor structure, physical space is a limiting constraint in such wiring. For example, it can be useful to wire from the frontside of the structure to a source/drain (S/D) epitaxial for the bottom device (e.g., bottom FET). Similarly, it can be useful to wire from the backside of the structure to an S/D epitaxial of the top FET. However, such wiring occupies space between the cells of the structure, and along the full height of the stack. Further, this physical space becomes increasing constrained as semiconductor fabrication scales more cells into the same, limited physical space. As such, it can be challenging to accommodate wiring from the frontside to the bottom FET, and from the backside to the top FET, thus limiting the flexibility in the design of computer circuits with SFET devices.

### SUMMARY

Embodiments are disclosed for a semiconductor structure. The semiconductor structure includes a standard logic cell having a top field effect transistor (FET) and a bottom FET. Further, the top FET includes multiple top channels, Additionally, the top channels are in contact with a first dielectric liner of a first gate cut region. Further, the bottom FET includes multiple bottom channels. Additionally, the bottom channels are in contact with a second dielectric liner of a second gate cut region. Further, the top FET and the bottom FET share a gate. Additionally, the top FET is disposed in an offset position with respect to the bottom FET. Such embodiments can provide SFET semiconductor structures capable of more flexibly designed circuits in the relatively limited, physical space of SFET semiconductor structures, thus providing improved performance, power savings, and the like.

Embodiments are disclosed for a semiconductor structure. The semiconductor structure includes a standard logic cell having a top field effect transistor (FET) and a bottom FET. Further, the top FET includes multiple top channels, Additionally, the top channels are in contact with a first dielectric liner of a first gate cut region. Further, the bottom FET includes multiple bottom channels. Additionally, the bottom channels are in contact with a second dielectric liner of a second gate cut region. Further, the top FET and the bottom FET share a gate. Additionally, the top FET is disposed in an offset position with respect to the bottom FET. Further, the semiconductor structure includes a bonding oxide layer, where the bonding oxide layer is in contact with the first dielectric liner. Additionally, a gate metal is disposed between the bonding oxide layer and the second dielectric liner. Such embodiments can provide SFET semiconductor structures capable of more flexibly designed circuits in the relatively limited, physical space of SFET semiconductor structures, thus providing improved performance, power savings, and the like.

Embodiments are disclosed for a semiconductor structure. The semiconductor structure includes a standard logic cell having a top field effect transistor (FET) and a bottom FET. Further, the top FET includes multiple top channels, Additionally, the top channels are in contact with a first dielectric liner of a first gate cut region. Further, the bottom FET includes multiple bottom channels. Additionally, the bottom channels are in contact with a second dielectric liner of a second gate cut region. Further, the top FET and the bottom FET share a gate. Additionally, the top FET is disposed in an offset position with respect to the bottom FET. Further, the deep via connects a bottom source/drain (S/D) epitaxial to a frontside interconnect. Such embodiments can provide SFET semiconductor structures capable of more flexibly designed circuits in the relatively limited, physical space of SFET semiconductor structures, thus providing improved performance, power savings, and the like.

Embodiments are disclosed for a semiconductor structure. The semiconductor structure includes a standard logic cell having a top field effect transistor (FET) and a bottom FET. Further, the top FET includes multiple top channels, Additionally, the top channels are in contact with a first dielectric liner of a first gate cut region. Further, the bottom FET includes multiple bottom channels. Additionally, the bottom channels are in contact with a second dielectric liner of a second gate cut region. Further, the top FET and the bottom FET share a gate. Additionally, the top FET is disposed in an offset position with respect to the bottom FET. Further, the deep via connects a top S/D epitaxial to a backside interconnect. Such embodiments can provide SFET semiconductor structures capable of more flexibly designed circuits in the relatively limited, physical space of SFET semiconductor structures, thus providing improved performance, power savings, and the like.

Embodiments are disclosed for a method of fabricating a semiconductor structure. The method includes forming a bottom FET with a bottom merged active device. Additionally, the method includes forming a top FET with a top merged active device, where the top FET is disposed in an offset position from the bottom FET. Further, the method includes forming a bonding oxide opening to a bottom dummy gate. Additionally, the method includes forming a replacement gate for the top FET and the bottom FET. Further, the method includes forming a first gate cut that separates the top merged active device into two top active regions.

Additionally, the first gate cut separates the bottom merged active device into two bottom active regions. Further, the method includes forming a second gate cut. Additionally, the top FET and bottom FET form a standard logic cell between the first gate cut and the second gate cut. Further, the top channels are attached to the first gate cut and the bottom channels are attached to the second gate cut. Additionally, the method includes forming a deep via within the first gate cut. Such embodiments can provide SFET semiconductor structures capable of more flexibly designed circuits in the relatively limited, physical space of SFET semiconductor structures, thus providing improved performance, power savings, and the like.

The present Summary is not intended to illustrate each aspect of, every implementation of, and/or every embodiment of the present disclosure. These and other features and advantages will become apparent from the following detailed description of the present embodiment(s), taken in conjunction with the accompanying drawings.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are illustrative of certain embodiments and do not limit the disclosure.

FIG. 1-1 is a cross-sectional view of semiconductor structures during intermediate steps of a method for forming offset staggered stacked field effect transistor (SFET) (e.g., forksheet) semiconductor structures, in accordance with some embodiments of the present disclosure.

FIG. 1-2 is a cross-sectional view of semiconductor structures during intermediate steps of a method for forming offset staggered stacked forksheet semiconductor structures, in accordance with some embodiments of the present disclosure.

FIG. 1-3 is a cross-sectional view of semiconductor structures during intermediate steps of a method for forming offset staggered stacked forksheet semiconductor structures, in accordance with some embodiments of the present disclosure.

FIG. 1-4 is a cross-sectional view of semiconductor structures during intermediate steps of a method for forming offset staggered stacked forksheet semiconductor structures, in accordance with some embodiments of the present disclosure.

FIG. 1-5 is a cross-sectional view of semiconductor structures during intermediate steps of a method for forming offset staggered stacked forksheet semiconductor structures, in accordance with some embodiments of the present disclosure.

FIG. 1-6 is a cross-sectional view of semiconductor structures during intermediate steps of a method for forming offset staggered stacked forksheet semiconductor structures, in accordance with some embodiments of the present disclosure.

FIG. 1-7 is a cross-sectional view of semiconductor structures during intermediate steps of a method for forming offset staggered stacked forksheet semiconductor structures, in accordance with some embodiments of the present disclosure.

FIG. 1-8 is a cross-sectional view of semiconductor structures during intermediate steps of a method for forming offset staggered stacked forksheet semiconductor structures, in accordance with some embodiments of the present disclosure.

FIG. 1-9 is a cross-sectional view of semiconductor structures during intermediate steps of a method for forming offset staggered stacked forksheet semiconductor structures, in accordance with some embodiments of the present disclosure.

FIG. 1-10 is a cross-sectional view of semiconductor structures during intermediate steps of a method for forming offset staggered stacked forksheet semiconductor structures, in accordance with some embodiments of the present disclosure.

FIG. 1-11 is a cross-sectional view of semiconductor structures during intermediate steps of a method for forming offset staggered stacked forksheet semiconductor structures, in accordance with some embodiments of the present disclosure.

FIG. 1-12 is a cross-sectional view of semiconductor structures during intermediate steps of a method for forming offset staggered stacked forksheet semiconductor structures, in accordance with some embodiments of the present disclosure.

FIG. 2 represents a process flow chart of a method for forming offset staggered stacked forksheet semiconductor structures, in accordance with some embodiments of the present disclosure.

FIGS. 3-1 through 3-2 represent a process flow chart of a method for forming offset staggered stacked forksheet semiconductor structures, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the particular embodiments described. On the contrary, the intention is to cover all modifications, equivalents, and alternatives falling within the spirit and scope of the present disclosure.

### DETAILED DESCRIPTION

Example 1 is a semiconductor structure. The semiconductor structure includes a standard logic cell including: a top field effect transistor (FET) including a plurality of top channels, where the plurality of top channels are in contact with a first dielectric liner of a first gate cut region; and a bottom FET including a plurality of bottom channels, where the plurality of bottom channels are in contact with a second dielectric liner of a second gate cut region, where the top FET and the bottom FET share a gate, and where the top FET is disposed in an offset position with respect to the bottom FET. Such embodiments can provide stacked FET semiconductor structures capable of more flexibly designed circuits, and improved performance, power savings, and the like in the increasingly limited space of stacked FET semiconductor structures.

Example 2 includes the semiconductor structure of example 1, including or excluding optional features. In this example, the semiconductor structure includes a bonding oxide layer, where the bonding oxide layer is in contact with the first dielectric liner, and where a gate metal is disposed between the bonding oxide layer and the second dielectric liner. Such embodiments can provide stacked FET semiconductor structures capable of more flexibly designed circuits, and improved performance, power savings, and the like in the increasingly limited space of stacked FET semiconductor structures.

Example 3 includes the semiconductor structure of any one of examples 1 to 2, including or excluding optional features. In this example, the first gate cut region includes the first dielectric liner and a dielectric fill, where the first dielectric liner includes a first dielectric that is different than the dielectric fill. Such embodiments can provide stacked FET semiconductor structures capable of more flexibly designed circuits, and improved performance, power savings, and the like in the increasingly limited space of stacked FET semiconductor structures.

Example 4 includes the semiconductor structure of any one of examples 1 to 3, including or excluding optional features. In this example, the second gate cut region includes the second dielectric liner and a deep via. Such embodiments can provide stacked FET semiconductor structures capable of more flexibly designed circuits, and improved performance, power savings, and the like in the increasingly limited space of stacked FET semiconductor structures.

Example 5 includes the semiconductor structure of any one of examples 1 to 4, including or excluding optional features. In this example, the deep via connects a bottom source/drain (S/D) epitaxial to a frontside interconnect. Such embodiments can provide stacked FET semiconductor structures capable of more flexibly designed circuits, and improved performance, power savings, and the like in the increasingly limited space of stacked FET semiconductor structures.

Example 6 includes the semiconductor structure of any one of examples 1 to 5, including or excluding optional features. In this example, the deep via connects a top S/D epitaxial to a backside interconnect. Such embodiments can provide stacked FET semiconductor structures capable of more flexibly designed circuits, and improved performance, power savings, and the like in the increasingly limited space of stacked FET semiconductor structures.

Example 7 includes the semiconductor structure of any one of examples 1 to 4, including or excluding optional features. In this example, the first gate cut region separates a top merged active device into two top active devices, and where the first gate cut region separates a bottom merged active device into two bottom active devices. Such embodiments can provide stacked FET semiconductor structures capable of more flexibly designed circuits, and improved performance, power savings, and the like in the increasingly limited space of stacked FET semiconductor structures.

Example 8 is a semiconductor structure. The semiconductor structure includes a standard logic cell including: a top field effect transistor (FET) including a plurality of top channels, where the plurality of top channels are in contact with a first dielectric liner of a first gate cut region; and a bottom FET including a plurality of bottom channels, where the plurality of bottom channels are in contact with a second dielectric liner of a second gate cut region, and where the top FET and the bottom FET share a gate, and where the top FET is disposed in an offset position with respect to the bottom FET, and where the first gate cut region separates a top merged active device into two top active devices, and where the first gate cut region separates a bottom merged active device into two bottom active devices. Such embodiments can provide stacked FET semiconductor structures capable of more flexibly designed circuits, and improved performance, power savings, and the like in the increasingly limited space of stacked FET semiconductor structures.

Example 9 includes the semiconductor structure of example 8, including or excluding optional features. In this example, the semiconductor structure includes a bonding oxide layer, where the bonding oxide layer is in contact with the first dielectric liner, and where a gate metal is disposed between the bonding oxide layer and the second dielectric liner. Such embodiments can provide stacked FET semiconductor structures capable of more flexibly designed circuits, and improved performance, power savings, and the like in the increasingly limited space of stacked FET semiconductor structures.

Example 10 includes the semiconductor structure of any one of examples 8 to 9, including or excluding optional features. In this example, the first gate cut region includes the first dielectric liner and a dielectric fill, where the first dielectric liner includes a first dielectric that is different than the dielectric fill. Such embodiments can provide stacked FET semiconductor structures capable of more flexibly designed circuits, and improved performance, power savings, and the like in the increasingly limited space of stacked FET semiconductor structures.

Example 11 includes the semiconductor structure of any one of examples 8 to 10, including or excluding optional features. In this example, the second gate cut region includes the second dielectric liner and a deep via. Such embodiments can provide stacked FET semiconductor structures capable of more flexibly designed circuits, and improved performance, power savings, and the like in the increasingly limited space of stacked FET semiconductor structures. Such embodiments can provide stacked FET semiconductor structures capable of more flexibly designed circuits, and improved performance, power savings, and the like in the increasingly limited space of stacked FET semiconductor structures.

Example 12 includes the semiconductor structure of any one of examples 8 to 11, including or excluding optional features. In this example, the deep via connects a bottom source/drain (S/D) epitaxial to a frontside interconnect. Such embodiments can provide stacked FET semiconductor structures capable of more flexibly designed circuits, and improved performance, power savings, and the like in the increasingly limited space of stacked FET semiconductor structures.

Example 13 includes the semiconductor structure of any one of examples 8 to 12, including or excluding optional features. In this example, the deep via connects a top S/D epitaxial to a backside interconnect. Such embodiments can provide stacked FET semiconductor structures capable of more flexibly designed circuits, and improved performance, power savings, and the like in the increasingly limited space of stacked FET semiconductor structures.

Example 14 is a method for fabricating a semiconductor structure, the method. The method includes forming a bottom FET with a bottom merged active device; forming a top FET with a top merged active device, where the top FET is disposed in an offset position from the bottom FET; forming a bonding oxide opening to a bottom dummy gate; forming a replacement gate for the top FET and the bottom FET; forming a first gate cut; forming a second gate cut, where the top FET and bottom FET form a standard logic cell between the first gate cut and the second gate cut, and where a plurality of top channels are attached to the first gate cut and where a plurality of bottom channels are attached to the second gate cut; and forming a deep via within the first gate cut. Such embodiments can provide stacked FET semiconductor structures capable of more flexibly designed circuits, and improved performance, power savings, and the like in the increasingly limited space of stacked FET semiconductor structures.

Example 15 includes the method of example 14, including or excluding optional features. In this example, the deep via connects a top S/D of the top FET to a backside interconnect. Such embodiments can provide stacked FET semiconductor structures capable of more flexibly designed circuits, and improved performance, power savings, and the like in the increasingly limited space of stacked FET semiconductor structures.

Example 16 includes the method of any one of examples 14 to 15, including or excluding optional features. In this example, the deep via connects a bottom S/D of the bottom FET to a frontside interconnect. Such embodiments can provide stacked FET semiconductor structures capable of more flexibly designed circuits, and improved performance, power savings, and the like in the increasingly limited space of stacked FET semiconductor structures.

Example 17 includes the method of any one of examples 14 to 16, including or excluding optional features. In this example, the method includes removing the bottom dummy gate through the bonding oxide opening to generate a void. Such embodiments can provide stacked FET semiconductor structures capable of more flexibly designed circuits, and improved performance, power savings, and the like in the increasingly limited space of stacked FET semiconductor structures.

Example 18 includes the method of any one of examples 14 to 17, including or excluding optional features. In this example, the method includes forming the replacement gate by filling the void using a high-k gate metal. Such embodiments can provide stacked FET semiconductor structures capable of more flexibly designed circuits, and improved performance, power savings, and the like in the increasingly limited space of stacked FET semiconductor structures.

Example 19 includes the method of any one of examples 14 to 18, including or excluding optional features. In this example, the high-k gate metal connects the top FET and the bottom FET. Such embodiments can provide stacked FET semiconductor structures capable of more flexibly designed circuits, and improved performance, power savings, and the like in the increasingly limited space of stacked FET semiconductor structures.

Example 20 includes the method of any one of examples 14 to 19, including or excluding optional features. In this example, the first gate cut region separates the top merged active device into two top active devices, and where the first gate cut region separates the bottom merged active device into two bottom active devices. Such embodiments can provide stacked FET semiconductor structures capable of more flexibly designed circuits, and improved performance, power savings, and the like in the increasingly limited space of stacked FET semiconductor structures.

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the example embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub lithographic” may refer to a dimension or size less than current dimensions achievable by photolithographic processes, and the term “lithographic” may refer to a dimension or size equal to or greater than current dimensions achievable by photolithographic processes. The sub lithographic and lithographic dimensions may be determined by a person of ordinary skill in the art at the time the application is filed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device having a dummy fin removed from within an array of tight pitch fins according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping, and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As stated previously, in an SFET semiconductor structure, physical space is a limiting constraint in the wiring of the devices. Further, this physical space becomes increasing constrained as semiconductor fabrication scales more cells into the same, limited physical space. As such, it can be challenging to accommodate wiring schemes that pass from the frontside to the bottom FET, and from the backside to the top FET, thus limiting the flexibility in the design of computer circuits with SFET devices.

Accordingly, some embodiments of the present disclosure provide an offset staggered stacked forksheet semiconductor structure, that merges the top and bottom FETs in a single cell. In this way, such embodiments can increase the available space between cells for wiring from the frontside to the S/D epitaxial of the bottom FET, and wiring from the backside to the S/D epitaxial of the top FET. In this way, such embodiments can provide SFET semiconductor structures capable of more flexibly designed circuits, and improved performance, power savings, and the like in the relatively limited, physical space of SFET semiconductor structures. However, some embodiments of the present disclosure may not achieve such advantages.

The following figures include top and cross-sectional views of example semiconductor structures produced by a fabrication process for forming offset staggered stacked forksheet semiconductors, in accordance with some embodiments of the present disclosure. For clarity, not all elements are labelled in these figures. Rather, representative elements are labelled, with similar elements being indicated by position, size, shape, hash lines (or lack thereof), and the like, in subsequent figures.

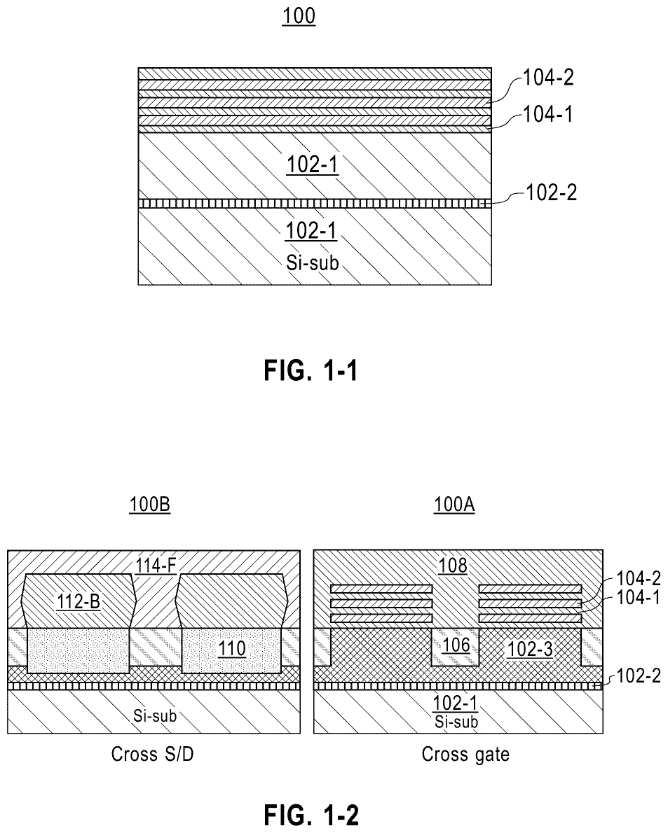

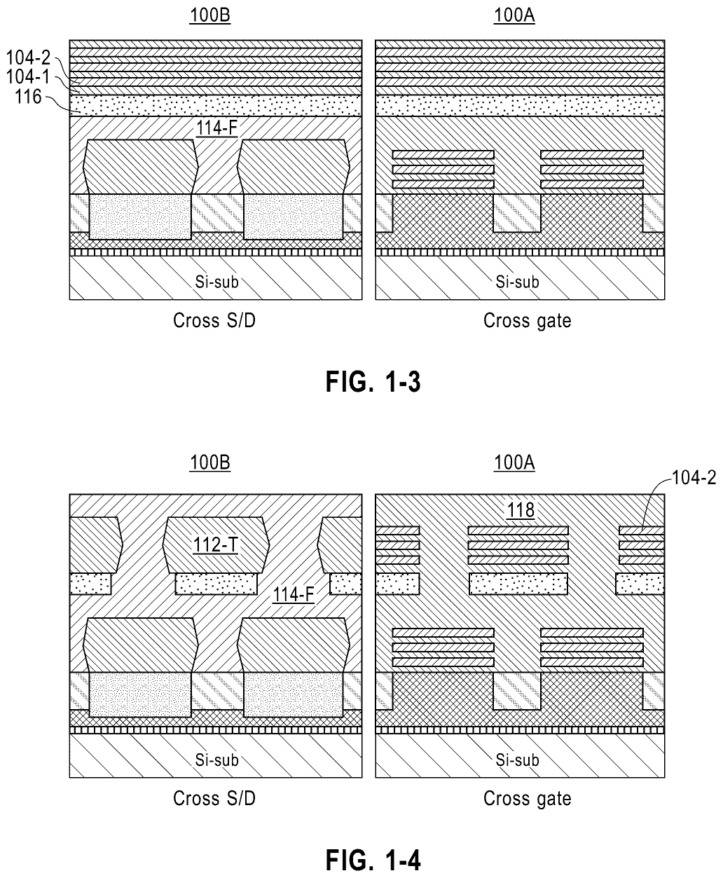

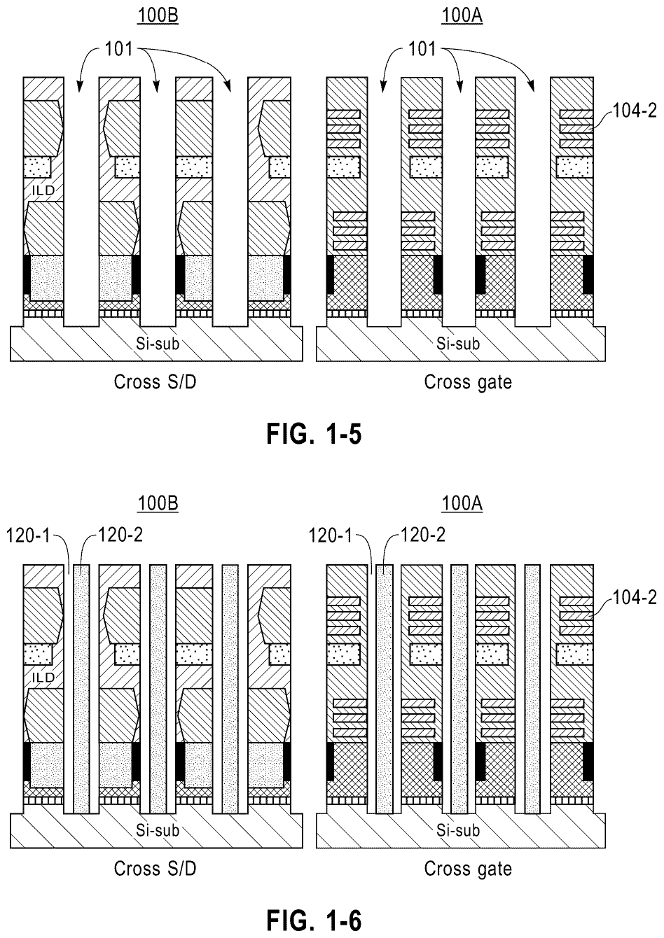

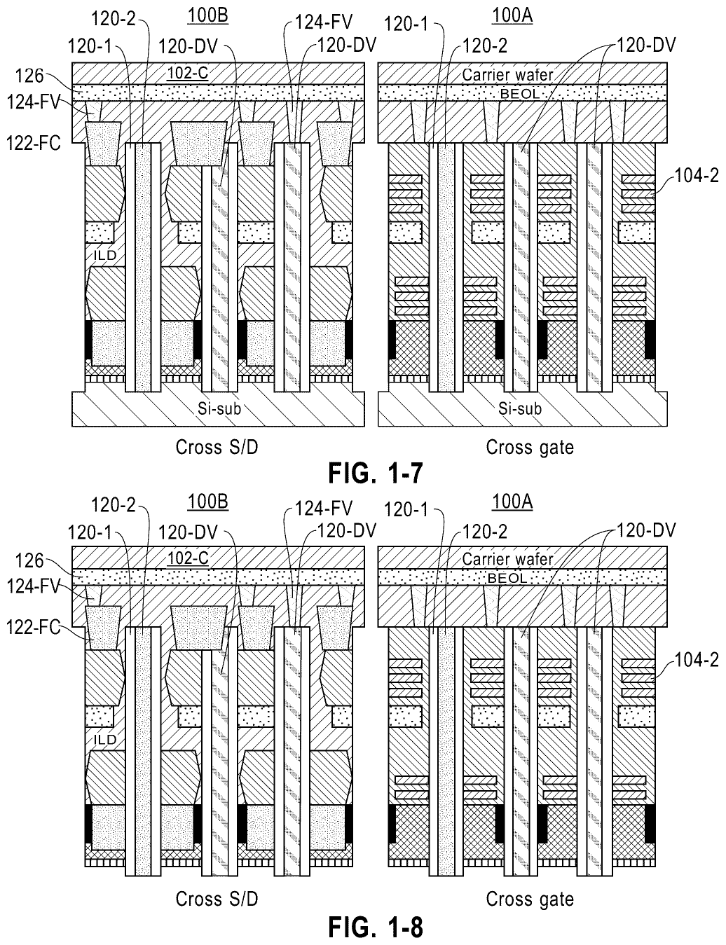

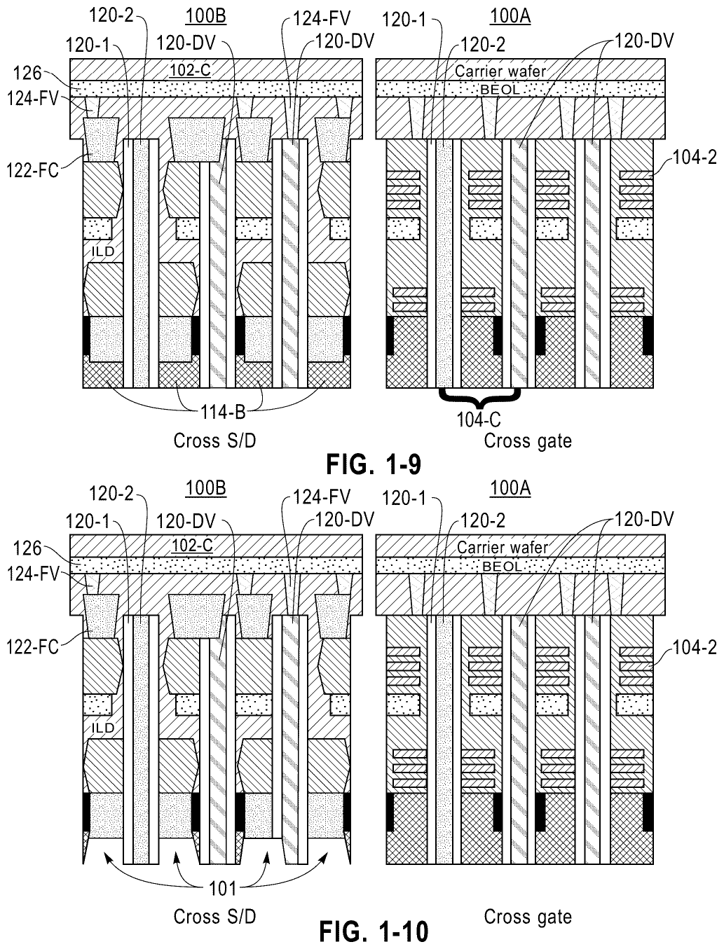

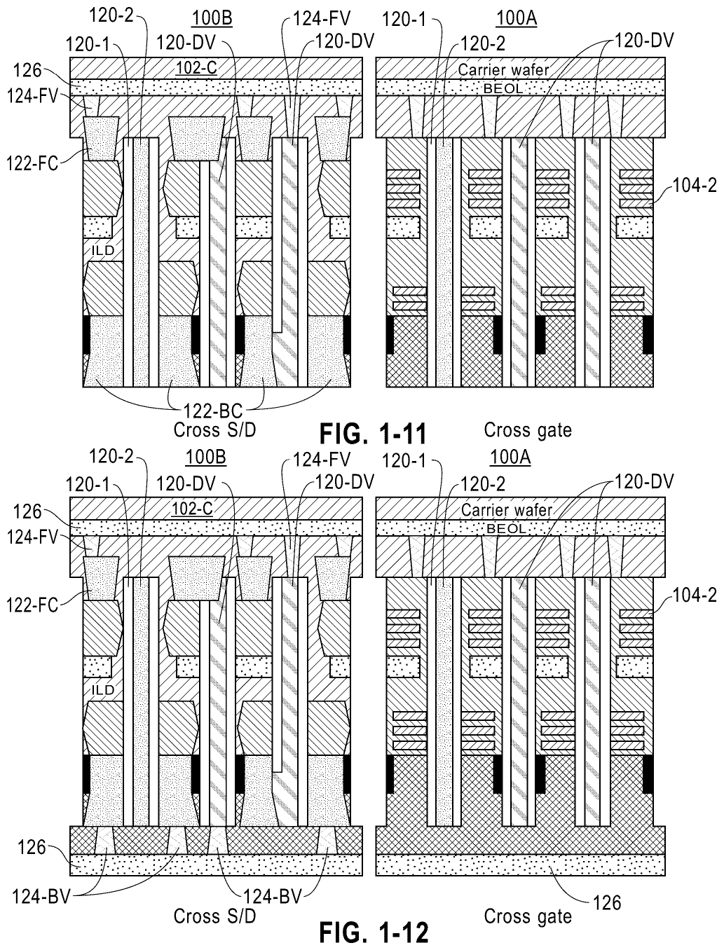

FIG. 1-1 is cross-sectional view of semiconductor structure 100 during intermediate steps of a method for forming offset staggered stacked forksheet semiconductors, in accordance with some embodiments of the present disclosure.

The semiconductor structure in FIG. 1-1 may result from a fabrication method wherein materials constituting each of the elements is deposited, applied, and otherwise arranged as shown. More specifically, the semiconductor structure 100 may represent a starting substrate having multiple nanosheets. As shown, the semiconductor structure 100 includes substrate layers 102-1, etch stop layer 102-2, sacrificial layers 104-1, and channel layers 104-2.

The substrate layers 102-1 can be a semiconductor or an insulator with an active surface semiconductor layer. More specifically, the substrate layers 102-1 can be crystalline, semi-crystalline, microcrystalline, or amorphous. Further, the substrate layers 102-1 can be (except for contaminants) a single element (e.g., Si), primarily (e.g., with doping) of a single element, for example, Si or Ge, or the substrate layers 102-1 can include a compound, for example, aluminum oxide (Al₂O₃), silicon dioxide (SiO₂), gallium arsenide (GaAs), silicon carbide (SiC), or SiGe. Additionally, the substrate layers 102-1 can have multiple material layers, for example, a semiconductor-on-insulator substrate (SeOI), a silicon-on-insulator substrate (SOI), germanium-on-insulator substrate (GeOI), or silicon-germanium-on-insulator substrate (SGOI). Further, the substrate layers 102-1 can have other layers forming the substrate layers 102-1, including high-k oxides and/or nitrides. In one or more embodiments, the substrate layers 102-1 can be a silicon wafer. In an embodiment, the substrate layers 102-1 can be a single crystal silicon wafer. The etch stop layer 102-2 may include, for example, silicon germanium, to facilitate thinning the substrate layers 102-1 to a desired thickness.

Additionally, the first sacrificial layer 104-1 separates the substrate layers 102-1 from the first channel layer 104-2. Further sacrificial layers 104-1 separate the channel layers 104-2. Additionally, the sacrificial layers 104-1 may be composed of silicon germanium (SiGe), having a particular percentage of germanium. For example, the sacrificial layers 104-1 may be 25 percent germanium (e.g., SiGe25).

The channel layers 104-2 may be silicon, or other suitable materials for the channels of a FET. A channel is the region of the FET underlying the gate structure. This region is disposed between the source and drain of the semiconductor device, and becomes conductive when the semiconductor device is turned on.

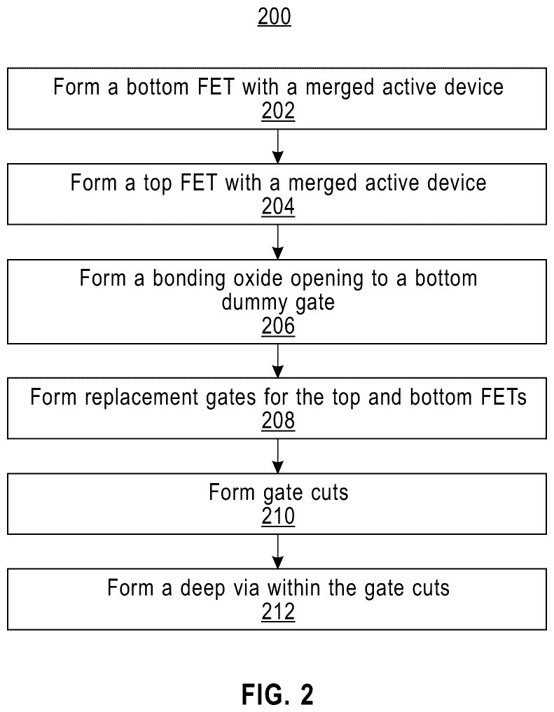

FIG. 1-2 is cross-sectional views of semiconductor structures 100A, 100B during intermediate steps of a method for forming offset staggered stacked forksheet semiconductors, in accordance with some embodiments of the present disclosure. More specifically, the semiconductor structures 100A, 100B respectively represent a cross-sectional view of S/D and cross-sectional view along the gate. Further, the semiconductor structures 100A, 100B result from forming the bottom device active region (RX), dummy gates, inner spacers (not shown), S/D epitaxials, and performing interlayer dielectric (ILD) fill and CMP on the semiconductor structure 100. Forming the bottom device active region involves forming a merged active region for the bottom device. With exception to the sacrificial layers 104-1, (which are removed to make room for the gates) the semiconductor structures 100A, 100B include the same elements described with respect to semiconductor structure 100. Additionally, however, the semiconductor structure 100A includes placeholder material 110, a bottom S/D epitaxial 112-B, and ILD layer 114-F. Further, semiconductor structure 100B includes a shallow trench isolation (STI) layer 106, and dummy gate materials 108.

With respect to the semiconductor structure 100A, the bottom device active region includes the fins 104 (having sacrificial layers 104-1 and channel layers 104-2), STI layer 106, and dummy gate materials 108. Forming the bottom device active region includes patterning material from the upper substrate layer (e.g., from substrate layers 102-1), sacrificial layers 104-1, and channel layers 104-2 to form fins 104. Additionally, forming the STI layer 106 involves depositing an ILD on the exposed substrate layer 102-1. Further, the dummy gate materials 108 are deposited on the fins 104 and the STI layer 106. Additionally, ILD 114-F deposition and CMP are performed to reveal dummy gate materials 108.

With respect to the semiconductor structure 100B, the bottom device active region includes the fins 104 (having placeholder material 110 and bottom S/D epitaxial 112-B 104-2), STI layer 106, and ILD layer 114-F. Forming the placeholder material 110 involves removing substrate after inner spacer formation (not shown), and forming placeholder material 110 by depositing material or forming selective epitaxial growth. Forming the bottom S/D epitaxials 112-B involves performing an epitaxial growth over exposed nanosheets (not shown) or from the placeholder material 110. The ILD layer 114-F is formed by an ILD fill between the gates (not shown) over exposed S/D epi and STI. The CMP on the deposited ILD layer 114-F. involves removing portions of the ILD layer 114-F to form a planarized surface with the rest of the semiconductor structure.

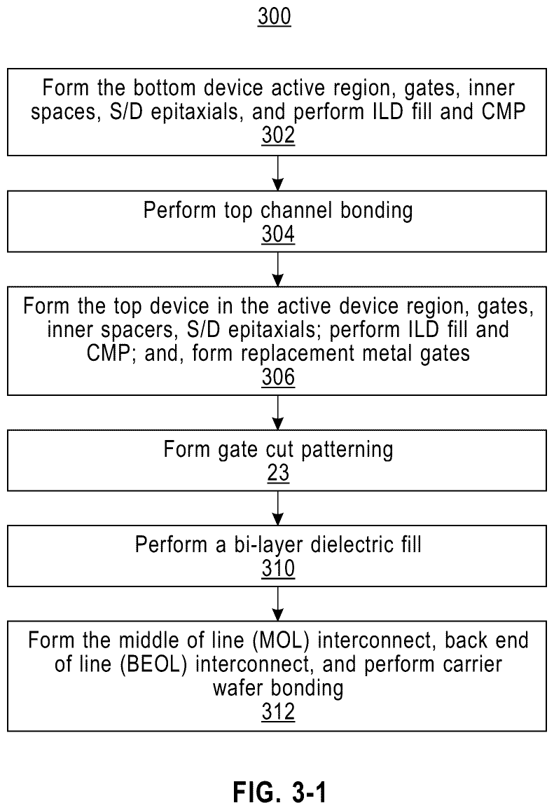

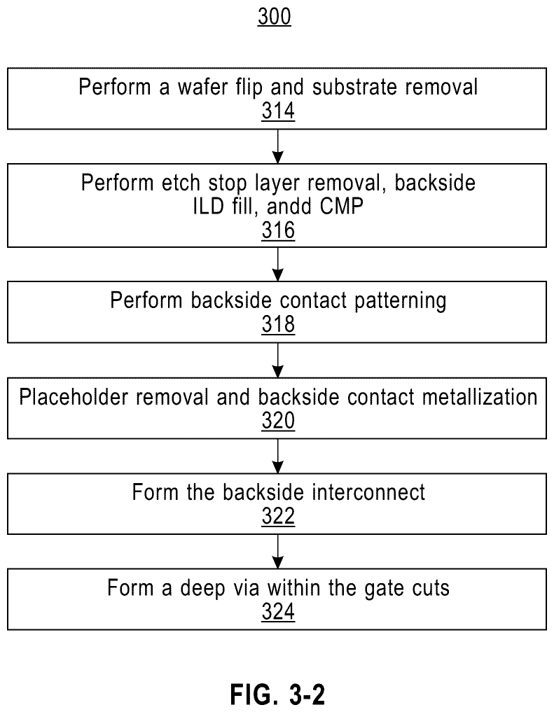

FIG. 1-3 is cross-sectional views of semiconductor structures 100A, 100B of a semiconductor structure during intermediate steps of a method for forming offset staggered stacked forksheet semiconductors, in accordance with some embodiments of the present disclosure. The semiconductor structures 100A, 100B of FIG. 1-3 result from bonding a top channel on the semiconductor structures 100A, 100B of FIG. 1-2.

A bonding dielectric (such as SiO2) is deposited over the semiconductor structures 100A, 100B shown in FIG. 1-2. Further, on a new Si wafer (not shown), nanosheet stacks having sacrificial layers 104-1 and channel layer 104-2 are epitaxially grown. Additionally, a bonding dielectric (such as SiO2) is deposited. Further, the new Si wafer is flipped, and bonded to the current wafer using a dielectric-to-dielectric bonding process. Further, the Si substrate removal is performed, leaving only the nanosheet stack left over the merged bonding oxide layer 116.

FIG. 1-4 is cross-sectional views of semiconductor structures 100A, 100B of a semiconductor structure during intermediate steps of a method for forming offset staggered stacked forksheet semiconductors, in accordance with some embodiments of the present disclosure. The semiconductor structures 100A, 100B result from performing top device active region patterning, forming gates and inner spacers (not shown), growing S/D epitaxials, performing ILD fill and CMP, and forming replacement metal gates on the semiconductor structures 100A, 100B of FIG. 1-3.

With respect to the semiconductor structure 100A, performing top device active region patterning involves forming a merged top active region. Further, the top active region is offset with respect to the bottom active region. More specifically, performing top device active region patterning involves removing the sacrificial layers 104-1, and portions of the channel layers 104-2 and bonding oxide layer 116 to form fins 104. Forming the gates 118 involves depositing dummy gate materials 108 over the fins 104 followed by gate lithography and etch. Further, the gate spacer is formed (not shown), fins between the gate are removed (not shown), and the SiGe indentation and inner (not shown) spacer formation are performed. Additionally, the upper S/D epi 112-T growth is performed. Further, the ILD layer 114-F is deposited followed by CMP to reveal the dummy gate materials 108. Further, forming the gates 118 involves removing the dummy gate materials 108 for both top and bottom devices using a selective etch process, removing the exposed sacrificial layer 104-1, and depositing a high-k metal gate (HKMG) material through the openings, to fill the voids left by the removal of the sacrificial layers 104-1, dummy gate materials 108, and bonding oxide layer 116.

FIG. 1-5 is cross-sectional views of semiconductor structures 100A, 100B of semiconductor structure 100B during intermediate steps of a method for forming offset staggered stacked forksheet semiconductor structures, in accordance with some embodiments of the present disclosure. The semiconductor structures 100A, 100B result from performing gate cut patterning on the semiconductor structures 100A, 100B of FIG. 1-4. Performing gate cut patterning involves removing substrate layers 102-1, etch stop layer 102-2, channel layers 104-2, STI layers 106, placeholder material 110, S/D epitaxials 112, ILD layers 114-F, bonding oxide layers 116, and replacement metal gate 118, to form trenches 101. Forming the trenches 101 provides access to the substrate layers 102-1 and channel layers 104-2. Further, the gate cut size is smaller than the opening size in bonding oxide, such that top gate and bottom gate are still connected with in an SFET CMOS cell, and within an SFET CMOS cell, bottom channels are attached to 1^{st} gate cut region, and top channels are attached to another gate cut region.

FIG. 1-6 is cross-sectional views of semiconductor structures 100A, 100B of a semiconductor structure during intermediate steps of a method for forming offset staggered stacked forksheet semiconductors, in accordance with some embodiments of the present disclosure. The semiconductor structures 100A, 100B result from performing a bi-layer dielectric fill on the semiconductor structures 100A, 100B of FIG. 1-5. With respect to semiconductor structures 100A, 100B, performing the bi-layer dielectric fill involves forming a dielectric liner 120-1 by depositing dielectric in the trenches 101, and removing horizontal portions of the material by anisotropic etching process to form a smaller trench (not shown) within the dielectric liner 120-1. Additionally, performing the bi-layer dielectric fill involves depositing an inner dielectric fill 120-2 in the smaller trench, using a second dielectric, having a different composition than the dielectric liner 120-1.

FIG. 1-7 is cross-sectional views of semiconductor structures 100A, 100B of a semiconductor structure during intermediate steps of a method for forming offset staggered stacked forksheet semiconductors, in accordance with some embodiments of the present disclosure. The semiconductor structures 100A, 100B result from forming deep via contact (120-DV) through gate cut regions by selectively etching the inner dielectric fill 120-2 with respect to 120-1, and forming the middle of line (MOL), a back end of line (BEOL) interconnect, and performing carrier wafer bonding on the semiconductor structures 100A, 100B of FIG. 1-6. With respect to semiconductor structures 100A, 100B, forming MOL involves depositing ILD material to form ILD layer 114-F on the semiconductor structures, and contact metallization. The contact metallization involves etching a trench through ILD layer 114-F and filling the trench with contact metal to form the frontside contacts 122-FC (e.g., in semiconductor structure 100A) and frontside vias 124-FV (e.g., in semiconductor structures 100A, 100B). Forming the BEOL interconnect 126 involves forming one or more interconnect dielectric material layers, and embedding within backside conductive wires, interconnects, and VIAs. Bonding the carrier wafer 102C involves bonding the carrier wafer 102C to the BEOL interconnect 126. The carrier wafer 102-C may be similar to the substrate layers 102-1.

FIG. 1-8 is cross-sectional views of semiconductor structures 100A, 100B of semiconductor structures during intermediate steps of a method for forming offset staggered stacked forksheet semiconductor structures, in accordance with some embodiments of the present disclosure. The semiconductor structures 100A, 100B result from performing a wafer flip and substrate removal on the semiconductor structures 100A, 100B of FIG. 1-8. Performing wafer flip involves reversing the vertical orientation of the semiconductor structures 100A, 100B. The substrate removal involves removing the exposed substrate layer 102-1. Even though the wafer flip changes the orientation of the semiconductor structures 100A, 100B, for the sake of clarity, the orientation of the semiconductor structures 100A, 100B remain the same in FIG. 1-8 as in FIG. 1-7.

FIG. 1-9 is cross-sectional views of semiconductor structures 100A, 100B of a semiconductor structure during intermediate steps of a method for forming offset staggered stacked forksheet semiconductors, in accordance with some embodiments of the present disclosure. The semiconductor structures 100A, 100B may result from performing etch stop layer removal, remaining substrate removal, and performing backside ILD fill and CMP on the semiconductor structures 100A, 100B of FIG. 1-8. Performing etch stop layer removal and remaining substrate removal involves a chemical and/or mechanical removal of the materials of substrate layer 102-1 and etch stop layer 102-2. Performing backside ILD fill (forming ILD layer 114-B) and CMP is similar to performing ILD fill and CMP as described with respect to FIG. 1-2. In the offset staggered configuration, a cell 104-C of the semiconductor structure 100B, is bounded by the inner dielectric fill 120-2 and the deep via 120-DV (bounded by the dielectric liners 120-1). Thus, a cell 204-C includes connected gates 118 in the top and bottom devices of the SFET.

FIG. 1-10 is cross-sectional views of semiconductor structures 100A, 100B of a semiconductor structure during intermediate steps of a method for forming offset staggered stacked forksheet semiconductors, in accordance with some embodiments of the present disclosure. Further, the semiconductor structures 100A, 100B result from performing backside contact patterning on the semiconductor structure 100B of FIG. 1-9. With respect to semiconductor structure 100A, backside contact patterning involves etching trenches 101 through ILD layer 114-B to expose the placeholder material 110.

FIG. 1-11 is cross-sectional views of semiconductor structures 100A, 100B of a semiconductor structure during intermediate steps of a method for forming offset staggered stacked forksheet semiconductors, in accordance with some embodiments of the present disclosure. The semiconductor structures 100A, 100B result from performing placeholder removal and backside contact metallization on the semiconductor structures 100A, 100B of FIG. 1-10. Performing placeholder removal involves a selective etch of the placeholder material 110, thus expanding the trenches (not shown) to expose the bottom S/D epitaxials 112-B. Additionally, backside contact metallization involves filling the trenches 101 with contact metal to form the backside contacts 122-BC.

FIG. 1-12 is cross-sectional views of semiconductor structures 100A, 100B of a semiconductor structure during intermediate steps of a method for forming offset staggered stacked forksheet semiconductors, in accordance with some embodiments of the present disclosure. The semiconductor structures 100A, 100B result from forming a backside interconnect on the semiconductor structures 100A, 100B of FIG. 1-11. More specifically, forming backside interconnect 128 involves fabricating the elements of the backside interconnect 128, such as, metallic lines, ILD material, and a heavy metal layer.

FIG. 2 represents a process flow chart of a method 200 for forming offset staggered stacked forksheet semiconductors, in accordance with some embodiments of the present disclosure. The method 200 may be similar to the method represented in FIGS. 1-1 through 1-12, to produce a semiconductor structure.

At operation 202, a fabrication tool can form a bottom FET with a merged active device. Forming the bottom FET involves forming the bottom active region, dummy gate, S/D epitaxial growth, and an ILD fill and CMP, described with respect to FIG. 1-2.

At operation 204, a fabrication tool can form a top FET with the merged active device, where the top FET is disposed offset to the bottom FET. Forming the top FET involves depositing: the bonding oxide layer 116 on the bottom active region, a sacrificial layer 104-1 on the bonding oxide layer 116, and alternating channel layers 104-2 and sacrificial layers 104-1, described with respect to FIG. 1-3. In this way, the top merged active region is formed offset with respect to the bottom merged active region.

At operation 206, a fabrication tool can form a bonding oxide opening to a bottom dummy gate. Forming the bonding oxide opening to the bottom dummy gate involves removing portions of sacrificial layers 104-1, channel layers 104-2, and the bonding oxide layer 116 to expose the bottom dummy gate (e.g., dummy gate materials 108). The operation 206 is further described with respect to FIG. 1-4.

At operation 208, a fabrication tool can form replacement gates for the top and bottom FETs. Forming the replacement gates (e.g., gates 118) involves filling the voids created by forming the bonding oxide opening, and removing the dummy gate materials 108, with a high-k metal gate material. The operation 208 is further described with respect to FIG. 1-4.

At operation 210, a fabrication tool can form a gate cut. Forming the gate cuts separates the merged active regions into two active regions. In this way, forming the gate cut can enable the configuration of a pair of top and bottom FETs into a standard logic cell, e.g., cell 104-C, described with respect to FIG. 1-9. In the cell 104-C, the top channels are attached to a dielectric liner of a first gate cut and the bottom channels of the cell are attached to a dielectric liner of a second gate cut, different from the first gate cut. The operation 210 is further described with respect to FIG. 1-5.

At operation 212, a fabrication tool can form a deep via within a gate cut, to wire a top S/D to the backside interconnect. Alternatively, the deep via can wire a backside contact to the frontside interconnect. Forming the deep vias (e.g., deep vias 102-DV), involves removing the inner dielectric fill 120-2, and filling the void formed by the removal with metal. The operation 208 is further described with respect to FIGS. 1-6 and 1-7.

FIGS. 3-1 through 3-2 represent a process flow chart of a method 300 for forming offset staggered stacked forksheet semiconductors, in accordance with some embodiments of the present disclosure. The method 300 may be similar to the method represented in FIGS. 1-1 through 1-12, to produce a semiconductor structure.

At operation 302, a fabrication tool can form the bottom device active region, gates, inner spacers, S/D epitaxials, and perform ILD fill and CMP, described with respect to FIG. 1-2. As stated previously, forming the bottom device active region, gates, inner spacers, and S/D epitaxials forms the substrate layers 102-1, etch stop layer 102-2, sacrificial layers 104-1, channel layers 104-2, STI layer 106, dummy gate materials 108, and bottom S/D epitaxials 112-B of semiconductor structures 100A, 100B. Further, performing the ILD fill involves forming the ILD layer 114 on the semiconductor structures 100A, 100B. Further, performing the CMP involves removing portions of the ILD fill to form a planarized surface for the ILD layer 114 with the rest of the semiconductor structure.

At operation 304, a fabrication tool may perform top channel bonding, described with respect to FIG. 1-3. Performing top channel bonding involves depositing the bonding oxide layer 116 on the semiconductor structures 100A, 100B. Additionally, top channel bonding involves depositing alternating sacrificial layers 104-1 and channel layers 104-2 on the bonding oxide layer 116.

At operation 306, a fabrication tool can form the top device in the active device region, gates, inner spacers, S/D epitaxials; perform ILD fill and CMP; and, form replacement metal gates, described with respect to FIG. 1-4. As stated previously, performing top device active region patterning involves removing portions of the sacrificial layers 104-1, and portions of the channel layers 104-2 to form fins. Additionally, forming the gates 118 involves forming an opening through the channel layers 104-2 and the bonding oxide layer 116 to expose the bottom dummy gate (e.g., dummy gate materials 108). Further, forming the gates 118 involves removing the dummy gate materials 108 using a selective etch process, and depositing a high-k metal gate (HKMG) material through the openings, to fill the voids left by the removal of the sacrificial layers 104-1, dummy gate materials 108, and bonding oxide layer 116.

With respect to the semiconductor structure 100B, performing the top device active region patterning involves removing the sacrificial layers 104-1, and the channel layers 104-2. Additionally, the top S/D epitaxials 112-T are formed by performing S/D epitaxial growth on the exposed bonding oxide layer 116. Performing ILD fill and CMP is described with respect to FIG. 1-2.

At operation 308, a fabrication tool can perform gate cut patterning, described with respect to FIG. 1-5. As stated previously, performing gate cut patterning involves removing substrate layers 102-1, etch stop layer 102-2, channel layers 104-2, STI layers 106, placeholder material 110, S/D epitaxials 112, ILD layers 114, bonding oxide layers 116, and replacement metal gate 118, to form trenches 101. Forming the trenches 101 provides access to the substrate layers 102-1 and channel layers 104-2.

At operation 310, a fabrication tool can perform a bi-layer dielectric fill, described with respect to FIG. 1-6. As stated previously, performing a bi-layer dielectric fill involves forming a dielectric liner 120-1 by depositing dielectric in the trenches 101, and removing horizontal portions of the material by anisotropic etching process to form a smaller trench within the dielectric liner 120-1. Additionally, performing the bi-layer dielectric fill involves depositing an inner dielectric fill 120-2 in the smaller trench, using a second dielectric, having a different composition than the dielectric liner 120-1.

At operation 312, a fabrication tool can form the MOL, BEOL interconnect, and perform carrier wafer bonding, described with respect to FIG. 1-7. As stated previously, forming the MOL involves depositing ILD material to form ILD layer 114-F on the semiconductor structures, and contact metallization. The contact metallization involves etching a trench through ILD layer 114-F and filling the trench with contact metal to form the frontside contacts 122-FC (e.g., in semiconductor structure 100A) and frontside vias 124-FV (e.g., in semiconductor structures 100A, 100B). Forming the BEOL interconnect 126 involves forming one or more interconnect dielectric material layers, and embedding within backside conductive wires, interconnects, and VIAs. Bonding the carrier wafer 102C can involve bonding the carrier wafer 102-C to the BEOL interconnect 126. The carrier wafer 102-C may be similar to the substrate layers 102-1.

At operation 314, a fabrication tool can perform a wafer flip and substrate removal, described with respect to FIG. 1-8. As stated previously, performing wafer flip involves reversing the vertical orientation of the semiconductor structures 100A, 100B. The substrate removal involves removing the exposed substrate layer 102-1.

At operation 316, a fabrication tool can perform etch stop layer removal, remaining substrate removal, backside ILD fill, and CMP, described with respect to FIG. 1-9. As stated previously, performing etch stop layer removal and remaining substrate removal can involve a chemical and/or mechanical removal of the materials of substrate layer 102-1 and etch stop layer 102-2. Performing backside ILD fill (forming ILD layer 114-B) and CMP is similar to performing ILD fill and CMP as described with respect to FIG. 1-2. In the offset staggered configuration, a cell 104-C of the semiconductor structure 100B, is bounded by the inner dielectric fill 120-2 and the deep via 120-DV (bounded by the dielectric liners 120-1). Thus, a cell 204-C includes connected gates 118 in the top and bottom devices of the SFET.

At operation 318, a fabrication tool may perform backside contact patterning, described with respect to FIG. 1-10. As stated previously, backside contact patterning involves etching trenches 101 through ILD layer 114-B to expose the placeholder material 110.

At operation 320, a fabrication tool can perform placeholder removal and backside contact metallization, described with respect to FIG. 1-11. As stated previously, performing placeholder removal can involve a selective etch of the placeholder material 110, thus expanding the trenches to expose the bottom S/D epitaxials 112-B. Additionally, backside contact metallization involves filling the trenches 101 with contact metal to form the backside contacts 122-BC in contact with the bottom S/D epitaxials 112-B.

At operation 322, a fabrication tool may form the backside interconnect, described with respect to FIG. 1-12. As stated previously, forming backside interconnect 128 involves fabricating the elements of the backside interconnect 128, such as, metallic lines, ILD material, and a heavy metal layer.

In these ways, some embodiments of the present disclosure can provide an offset staggered stacked forksheet semiconductor structure that provides wiring from the frontside (e.g., frontside contacts 122-FC and frontside vias 122-FV) to the bottom S/D epitaxial 112-B and wiring from the backside (e.g., backside contacts 122-BC and backside vias 124-BV) to the top S/D epitaxial 112-T. In this way, such embodiments can provide stacked forksheet semiconductor structures capable of more flexibly designed circuits, and improved performance, power savings, and the like in the increasingly limited space of stacked forksheet semiconductor structures. However, some embodiments of the present disclosure may not achieve such advantages.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. However, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks. When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category. For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations. Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to one skilled in the art. Therefore, it is intended that the following claims be interpreted as covering all such alterations and modifications as fall within the true spirit and scope of the invention.

What is claimed is:

1. A semiconductor structure comprising:
a standard logic cell comprising:
a top field effect transistor (FET) comprising a plurality of top channels, wherein the plurality of top channels are in contact with a first dielectric liner of a first gate cut region; and
a bottom FET comprising a plurality of bottom channels, wherein the plurality of bottom channels are in contact with a second dielectric liner of a second gate cut region, wherein the top FET and the bottom FET share a gate, and wherein the top FET is disposed in an offset position with respect to the bottom FET.

2. The semiconductor structure of claim 1, further comprising:
a bonding oxide layer, wherein the bonding oxide layer is in contact with the first dielectric liner, and wherein a gate metal is disposed between the bonding oxide layer and the second dielectric liner.

3. The semiconductor structure of claim 1, wherein the first gate cut region comprises the first dielectric liner and a dielectric fill, wherein the first dielectric liner comprises a first dielectric that is different than the dielectric fill.

4. The semiconductor structure of claim 1, wherein the second gate cut region comprises the second dielectric liner and a deep via.

5. The semiconductor structure of claim 4, wherein the deep via connects a bottom source/drain (S/D) epitaxial to a frontside interconnect.

6. The semiconductor structure of claim 4, wherein the deep via connects a top S/D epitaxial to a backside interconnect.

7. The semiconductor structure of claim 1, wherein the first gate cut region separates a top merged active device into two top active devices, and wherein the first gate cut region separates a bottom merged active device into two bottom active devices.

8. A semiconductor structure comprising:
a standard logic cell comprising:
a top field effect transistor (FET) comprising a plurality of top channels, wherein the plurality of top channels are in contact with a first dielectric liner of a first gate cut region; and
a bottom FET comprising a plurality of bottom channels, wherein the plurality of bottom channels are in contact with a second dielectric liner of a second gate cut region, and wherein the top FET and the bottom FET share a gate, and wherein the top FET is disposed in an offset position with respect to the bottom FET, and wherein the first gate cut region separates a top merged active device into two top active devices, and wherein the first gate cut region separates a bottom merged active device into two bottom active devices.

9. The semiconductor structure of claim 8, further comprising a bonding oxide layer, wherein the bonding oxide layer is in contact with the first dielectric liner, and wherein a gate metal is disposed between the bonding oxide layer and the second dielectric liner.

10. The semiconductor structure of claim 8, wherein the first gate cut region comprises the first dielectric liner and a dielectric fill, wherein the first dielectric liner comprises a first dielectric that is different than the dielectric fill.

11. The semiconductor structure of claim 8, wherein the second gate cut region comprises the second dielectric liner and a deep via.

12. The semiconductor structure of claim 11, wherein the deep via connects a bottom source/drain (S/D) epitaxial to a frontside interconnect.

13. The semiconductor structure of claim 11, wherein the deep via connects a top S/D epitaxial to a backside interconnect.

14. A method for fabricating a semiconductor structure, the method comprising:
forming a bottom FET with a bottom merged active device;
forming a top FET with a top merged active device, wherein the top FET is disposed in an offset position from the bottom FET;
forming a bonding oxide opening to a bottom dummy gate;
forming a replacement gate for the top FET and the bottom FET;
forming a first gate cut;
forming a second gate cut, wherein the top FET and the bottom FET form a standard logic cell between the first gate cut and the second gate cut, and wherein a plurality of top channels are attached to the first gate cut and wherein a plurality of bottom channels are attached to the second gate cut; and
forming a deep via within the first gate cut.

15. The method of claim 14, wherein the deep via connects a top S/D of the top FET to a backside interconnect.

16. The method of claim 14, wherein the deep via connects a bottom S/D of the bottom FET to a frontside interconnect.

17. The method of claim 14, further comprising removing the bottom dummy gate through the bonding oxide opening to generate a void.

18. The method of claim 17, further comprising forming the replacement gate by filling the void using a high-k gate metal.

19. The method of claim 18, wherein the high-k gate metal connects the top FET and the bottom FET.

20. The method of claim 14, wherein the first gate cut separates the top merged active device into two top active devices, and wherein the first gate cut separates the bottom merged active device into two bottom active devices.
